(19) United States
(12) Patent Application Publication
(10) Pub. No.: US 2014/0045318 A1
(43) Pub. Date: Feb. 13, 2014

(54) FORMING A TAPERED OXIDE FROM A THICK OXIDE LAYER

(71) Applicants: Vijay PARTHASARATHY, Sunnyvale, CA (US); Wayne B. GRABOWSKI, Los Altos, CA (US)

(72) Inventors: Vijay PARTHASARATHY, Sunnyvale, CA (US); Wayne B. GRABOWSKI, Los Altos, CA (US)

(73) Assignee: Power Integrations, Inc., San Jose, CA (US)

(21) Appl. No.: 13/572,492

(22) Filed: Aug. 10, 2012

(51) Int. Cl. H01L 21/76

(52) U.S. Cl. 438/430; 257/E21.54

(57) ABSTRACT

Processes for forming a tapered field plate dielectric in a semiconductor substrate are provided. The process may be used to form a variety of types of devices, such as Schottky diodes, HVFETs, JFET, IGBT, bipolar transistors, and the like. The process may include etching a trench in a semiconductor wafer, depositing an insulating layer on the semiconductor wafer to form a gap within the trench, depositing a masking layer on the insulating layer, and alternatingly etching the masking layer and the insulating layer to form a tapered field plate dielectric region.

### BACKGROUND

1. Field

The present disclosure relates generally to the fabrication of field plate dielectrics for high-voltage semiconductors and, more specifically, the present disclosure relates to the fabrication of tapered field plate dielectrics for high-voltage semiconductor devices.

2. Description of Related Art

Electronic devices use power to operate. Power is generally delivered through a wall socket as high voltage alternating current (ac). A device, typically referred to as a power converter or power supply, can be utilized to transform the high voltage ac input into a well regulated direct current (dc) output through an energy transfer element. One type of power converter is a switch mode power converter which are commonly used due to their high efficiency, small size, and low weight, to power many of today's electronics. Many switch mode power converters that provide electricity to electronics, such as tablet computers, smart phones, and LED lights, rely on power semiconductor devices that can handle high-voltages. For example, semiconductor devices in cell phone chargers may be required to handle peak voltages of up to 600 V without breaking down. Some of these high-voltage devices handle high voltages by spreading electric fields over larger areas of semiconductor, which prevents electric fields from exceeding breakdown thresholds. To aid in the spreading of the electrical fields, field plates are sometimes used.

One type of high voltage transistor is a vertical thin silicon (VTS) high voltage field effect transistor (HVFET). For example, FIG. 1 depicts an example VTS HVFET 10 built on wafer (N+ substrate) 11. VTS HVFET 10 includes source regions 15a (N+) and 15b (N+), body region 14 (P Body), and 13 (N extended drain region), which include a long drain extension in a silicon pillar. A potential applied to gates 17a and 17b may modulate a channel in body region 14 and control conduction between source regions 15a and 15b and drain regions 12 and 13. The potential of body region 14 may be controlled by body contact 16 (P). HVFET 10 also has field plate 18 separated from the silicon pillar by field plate dielectric 19 (Ox). Field plate 18 allows for an increase in breakdown voltage by spreading high voltage drops over larger areas in the extended drain region (i.e., spreading out electric fields).

### DESCRIPTION OF THE FIGURES

Non-limiting and non-exhaustive embodiments of the present invention are described with reference to the following figures, wherein like reference numerals refer to like parts throughout the various views unless otherwise specified.

FIG. 1 depicts an example HVFET structure with a field plate.

FIGS. 2A and 2B depict the formation of a mask for etching a trench for a tapered field plate and field plate dielectric region according to an example process for forming the tapered field plate dielectric region.

FIGS. 3A and 3B depict the etching of a trench according the example process for forming the tapered field plate dielectric region.

FIGS. 4A and 4B depict depositing a first insulating layer and filling a gap in the insulating layer with a mask layer according to the example process for forming the tapered field plate dielectric region.

FIG. 5 depicts etching the mask layer according to the example process for forming the tapered field plate dielectric region.

FIGS. 6A and 6B depict an isotropic etch of the insulating layer according to the example process for forming the tapered field plate dielectric region.

FIGS. 7A and 7B depict a second iteration of etching the mask layer according to the example process for forming the tapered field plate dielectric region.

FIGS. 8A and 8B depict a second iteration of an isotropic etch of the insulating layer according to the example process for forming the tapered field plate dielectric region.

FIGS. 9A and 9B depict a third iteration of etching the mask layer according to the example process for forming the tapered field plate dielectric region.

FIG. 10 depicts a tapered field plate dielectric region after several more iterations of etching the insulating layer and etching the mask layer according to the example process for forming the tapered field plate dielectric region.

FIG. 11 depicts a tapered field plate dielectric region having a less ideal profile.

FIGS. 12A and 12B depict deposition of a conductive material used to form the tapered field plate according to the example process for forming the tapered field plate dielectric region.

FIG. 13 depicts a flow chart for another example process for forming a tapered field plate dielectric.

### DETAILED DESCRIPTION

In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment”, “an embodiment”, “one example” or “an example” means that a particular feature, structure or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or subcombinations in one or more embodiments or examples. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

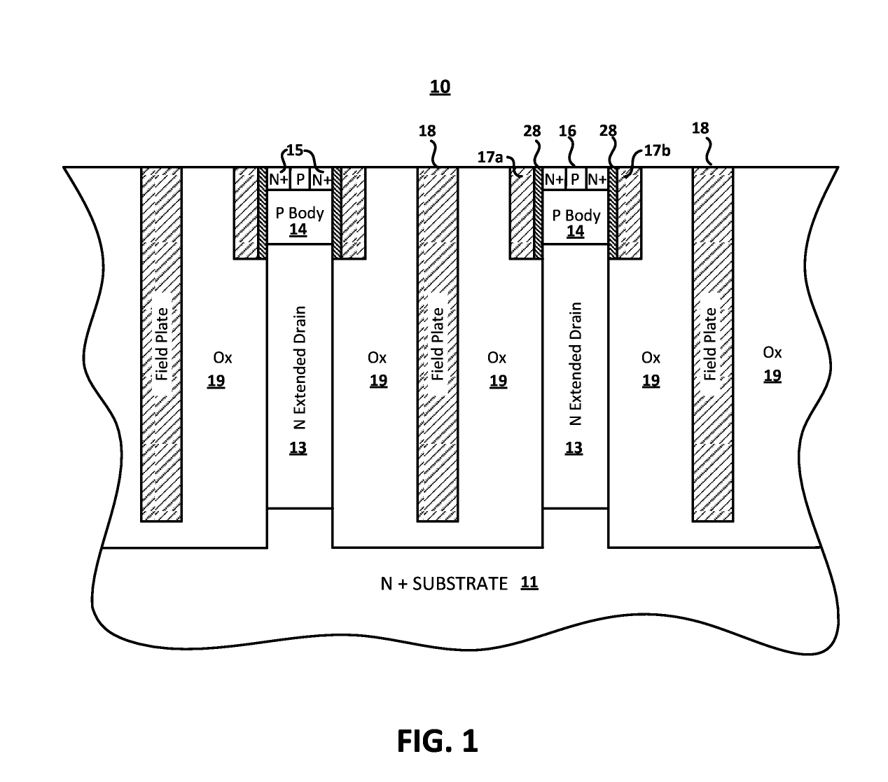

As discussed above, FIG. 1 depicts field plate 18 with field plate dielectric 19 that is substantially the same thickness along the depth of field plate 18. To develop a reliable device optimally, it may be suitable to maintain a constant electric field along extended drain region 13. In order to maintain a constant electric field, a graded doping profile for the extended drain region 13 may be necessary. In particular, the graded doping of drain region 13 may be gradually reduced along the depth as the surface of VTS device 10 is approached. In this manner, VTS device 10 is able to deplete between the extended drain region 13 and oxide 19 such that VTS device 10 is capable of supporting the maximum breakdown voltage. However, one disadvantage of having a graded doping profile may be having lighter doping closer to the surface of VTS device 10 that may cause a higher specific resistance and reduced efficiency.

According to the teachings of the present invention, the field plate dielectric thickness is varied along the depth of the device. In particular, the oxide thickness is minimal at the surface and increases along the depth of the device 10 until it approaches the bottom, which allows for increased doping of extended drain region 13 near the surface of VTS device 10. As a result, the specific resistance of VTS device 10 may be reduced by a factor of up to 3 to 4 times. In one example, specific resistance may be defined as the resistance that is inherent, based on material and design of the semiconductor, when there are substantially zero volts between the drain and source of VTS device 10. It may be appreciated that to improve efficiency of the semiconductor device, the specific resistance may be reduced to reduce power dissipation when the device is conducting. In one example, a varying thickness of the filed plate dielectric could be accomplished by tapering. In this manner, a constant distribution of doping may be accomplished.

An example process for forming a tapered field plate dielectric in a semiconductor substrate is described below. This example process may be useful with processes that form a variety of types of devices, such as Schottky diodes, HVFETs, JFET, IGBT, bipolar transistors, and the like. The tapered field plate dielectric fabrication is described with respect to figures depicting various stages of the example process. For ease of discussion, the example process is described with respect to the fabrication of one field plate dielectric region. However, it should be understood that only a portion of the substrate is depicted according to the figures. In practice, many devices (e.g., HVFETs) with field plates having tapered field plate dielectric regions are formed in parallel across the substrate.

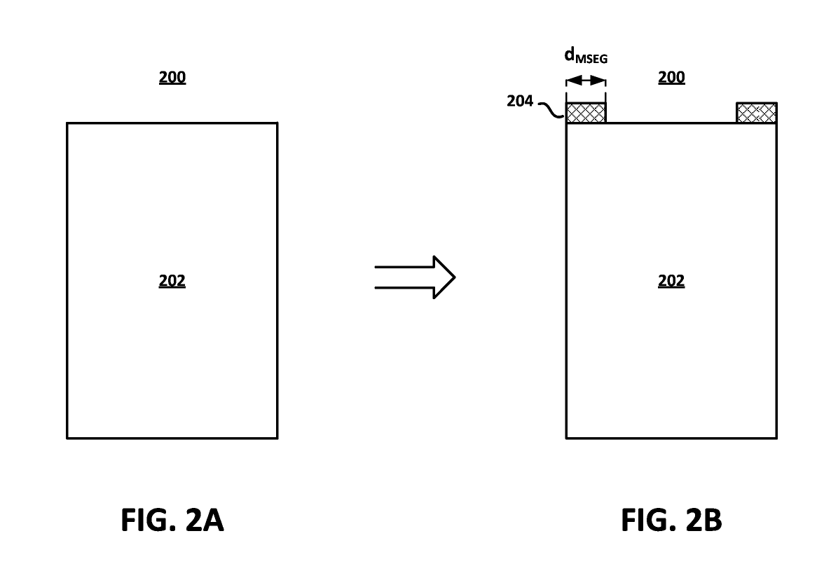

FIG. 2A depicts substrate 200, which includes wafer 202. Wafer 202 may be made of a variety of materials, such as, for example, silicon, silicon carbide, diamond, gallium arsenide, aluminum gallium arsenide, indium phosphide, gallium nitride, and the like. Wafer 202 may also be made of multiple different materials to form a hetero structure. Wafer 202 may also be formed of a base wafer (e.g., a silicon wafer) with other layers (e.g., epitaxially grown layers) grown on top of the silicon wafer.

FIG. 2B depicts substrate 200 after mask layer 204 has been deposited and patterned to define the location of the trench and field plate dielectric adjacent the silicon pillar where the semiconductor device will be located, which is roughly under the remaining portions of mask layer 204. Mask layer 204 may be a hardmask or a softmask. In one example, a soft mask may be a photoresist layer. In some variations of the example process, a protective layer may be deposited on the surface of wafer 202 prior to deposition and patterning of mask layer 204. The protective layer may protect the surface of wafer 202 from defects and damage during processing. If the example process does not use a protective layer (as depicted in FIG. 2B), a restoration step may be used to remove damage or clean defects from the surface of wafer 202 prior to performing other processing that involves the surface of wafer 202. For example, if a silicon wafer is used for wafer 202, a protective layer (not shown) may be, for example, a thermally grown oxide with a thickness of about 200 A. In one example, mask layer 204 segment may be have a length d_{MSEG} of 1-3 μm.

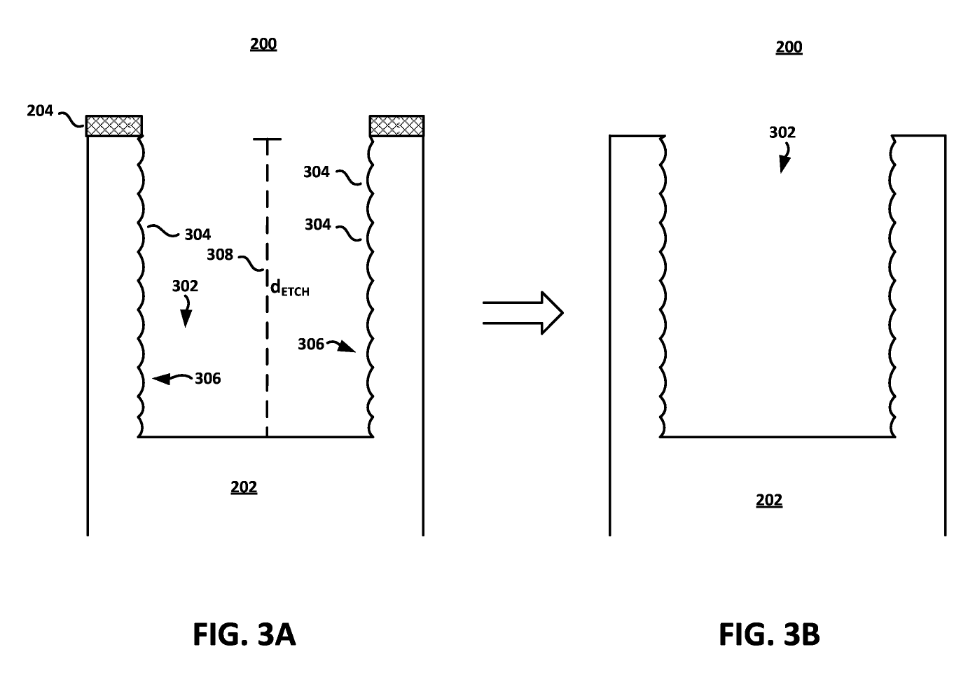

FIG. 3A depicts substrate 200 after trench 302 has been formed. In one example, a deep reactive ion etch (DRIE) step is used, which results in the formation of scallops 304 on the sidewalls 306 of trench 302. Trench 302 may be etched to depth d_{ETCH} 308, which, in one example, may be about 60 μm deep. It should be understood that other etch techniques could also be used that do not form scallops.

FIG. 3B depicts substrate 200 after mask layer 204 has been removed. Removing mask layer 204 may be accomplished with various steps. For example, if mask layer 204 is a photoresist mask, then a plasma ashing step may be used. In another example, if nitride or oxide are used for mask layer 204, then a phosphoric acid or hydrofluoric acid, respectively, etch step may be used.

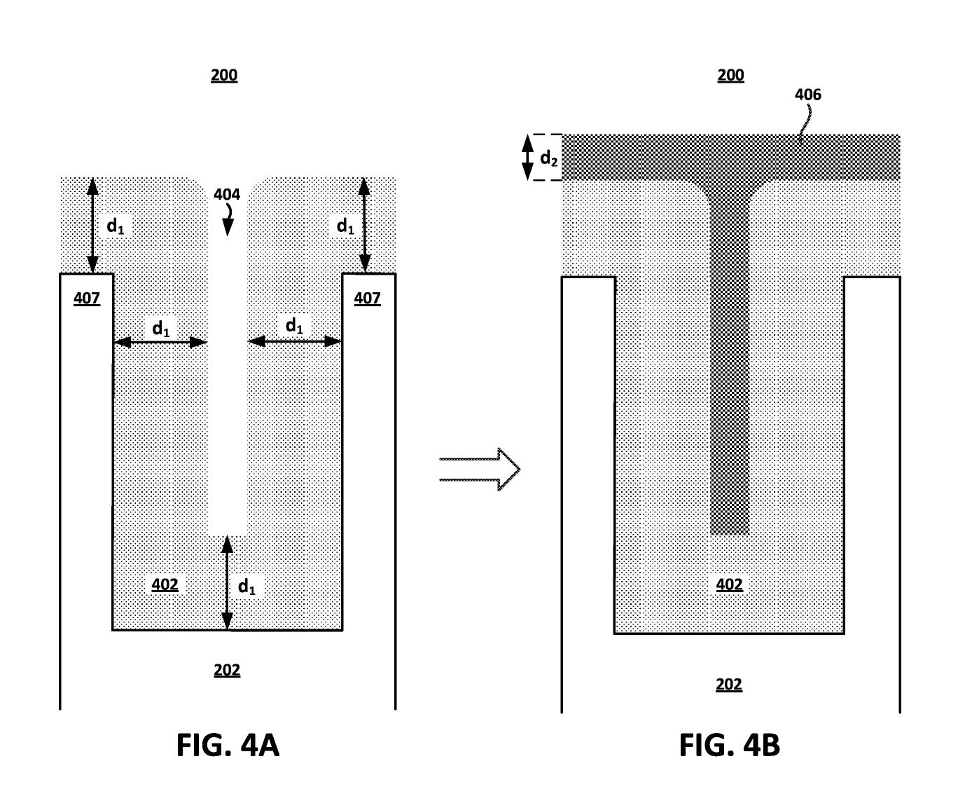

FIG. 4A depicts substrate 200 after insulating layer 402 is deposited. The process for depositing insulating layer 402 may be conformal so that approximately a thickness of d₁ of insulating material is present on vertical sidewalls 306, the bottom of trench 302, and on top of silicon pillars 407. Insulating layer 402 will also form gap 404. Insulating layer 402 may include silicon dioxide, silicon nitride, boron phosphide silicate glass, and the like. Processes, such as low pressure chemical vapor deposition, high density plasma, plasma enhanced chemical vapor deposition, and the like, may be used to deposit insulating layer 402. In one example, d₁ may be between 0.5 μm and 10 μm and gap 404 may be approximately 10 μm across.

Note that scallops 304 do not appear in FIG. 4A. The scallops may be removed from the sidewalls 306 of trench 302 prior to deposition of insulating layer 402. For example, if wafer 202 is silicon, then a thermal oxidation step may be used to consume the scallops and an oxide removal step may be used to remove the thermal oxide leaving a smoother sidewall. Alternatively, in variations of the example process, the scallops may remain. In other variations of the example process, the scallops may not be present due to the trench etch technique used or the scallops may be small enough that the scallops are not readily apparent or of concern.

FIG. 4B depicts substrate 200 after a fill mask layer 406 has been deposited on substrate 200. The thickness d₂ of fill mask layer 406 may be selected to ensure that gap 404 is completely filled. In other variations of the example process, mask layer 406 may not completely fill in gap 404. In particular, due to possible loafing of insulating layer 402 and fill mask layer 406, gap 404 may be pinched off, leaving a portion of gap 404 unfilled (not shown). In one example, material of fill mask layer 406 should have different etch properties as compared to the material of insulating layer 402 so that an etch recipe is available that is highly selective to etching the material of insulating layer 402 over the material of fill mask layer 406. For example, if insulating layer 402 is oxide, then mask layer 406 may be polysilicon.

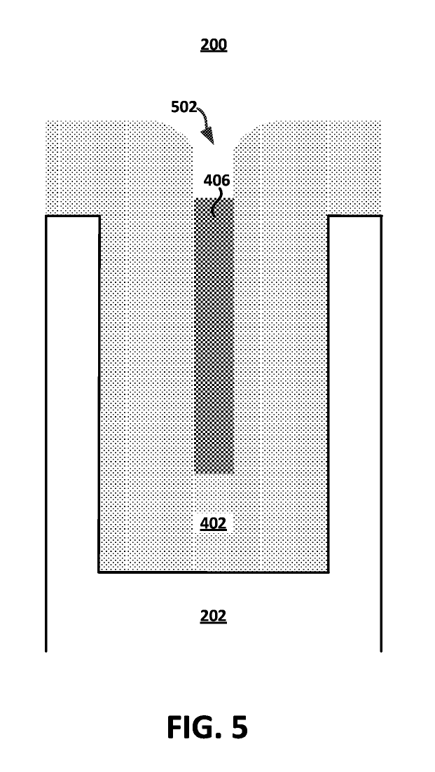

FIG. 5 depicts substrate 200 after mask layer 406 has gone through a planarized etch to remove fill mask layer 406 from the top surface of insulating layer 402 and from a portion of sidewalls of insulating layer 402 to recreate a portion of gap 404 (represented by region 502). In one example, FIG. 5 depicts a starting point of substrate 200 before proceeding with alternating cycles of etching insulating layer 402 and etching fill mask 406 to create a tapered field dielectric region.

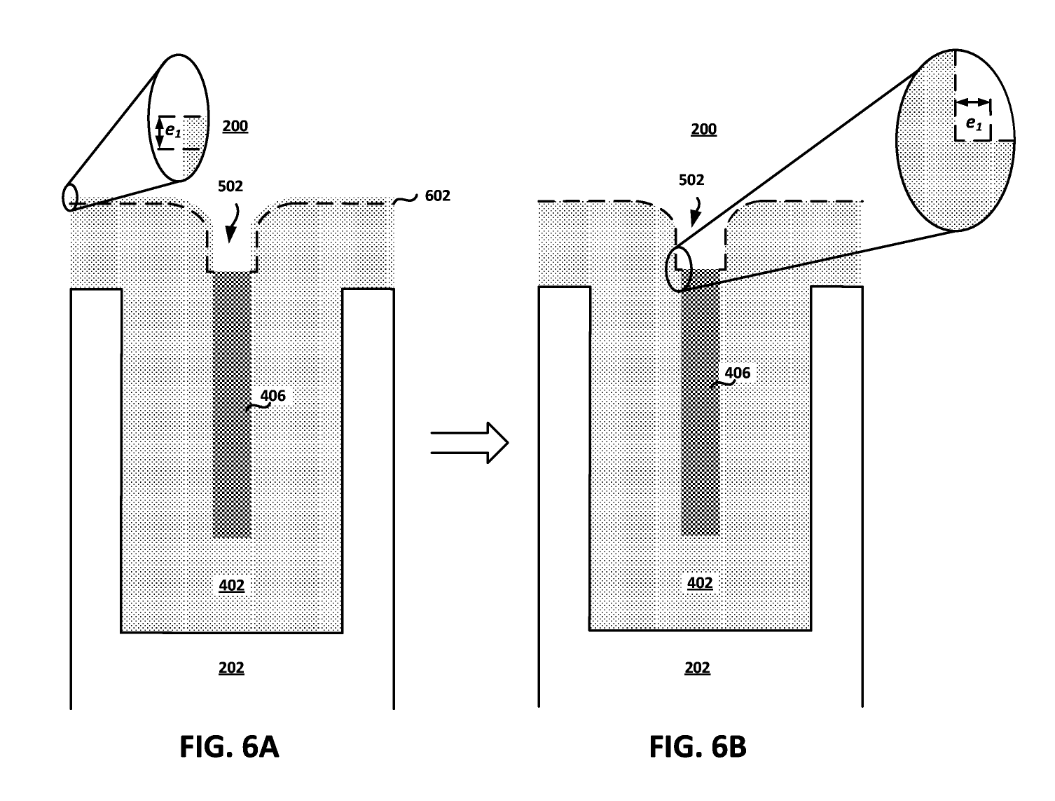

FIGS. 6A and 6B depict substrate 200 before and after an amount, e₁, of insulating layer 402 is isotropically etched, which means that approximately the same amount of material is etched regardless of the slope of the surface where the etching is taking place. In other words, the amount of insulating layer 402 that is etched from horizontal surfaces is approximately the same as the amount of insulating layer 402 that is etched from vertical surfaces. The isotropic nature of the etch is illustrated by line 602 that approximates the amount of insulating layer 402 that is removed from FIG. 6A to FIG. 6B during the etch. As can be seen from line 602, the thickness e₁ of insulating material removed is approximately constant across the surface of insulating layer 402. If the etch for insulating layer 402 is selected properly, such that the etch may be selected to have a high selectivity to insulating layer 402 over fill mask layer 406, very little of mask layer 406 should be etched. For example, if insulating layer 402 is oxide and fill mask layer 406 is polysilicon, then an etch step in aqueous hydrofluoric acid may be used to perform this isotropic etch. Note that because the sidewalls of insulating layer 402 adjacent to region 502 were exposed, the width of region 502 grew by approximately 2×e₁.

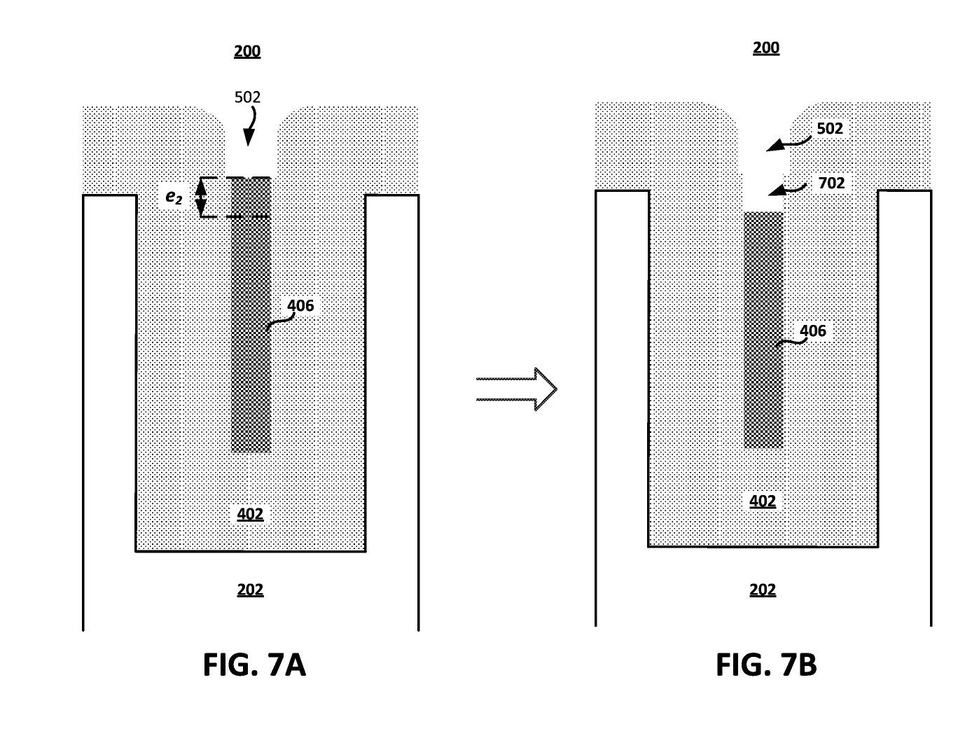

FIGS. 7A and 7B depict substrate 200 before and after etching a thickness e₂ of fill mask layer 406. By etching fill mask layer 406, a region 702 defined by the newly exposed sidewalls of insulating material 404 is formed below region 502. Region 702 is narrower than region 502 and has roughly the same width as region 502 had when it was first formed (see FIG. 5) since the initial width of region 702 and region 502 are both determined by the width of gap 404 (FIG. 4A).

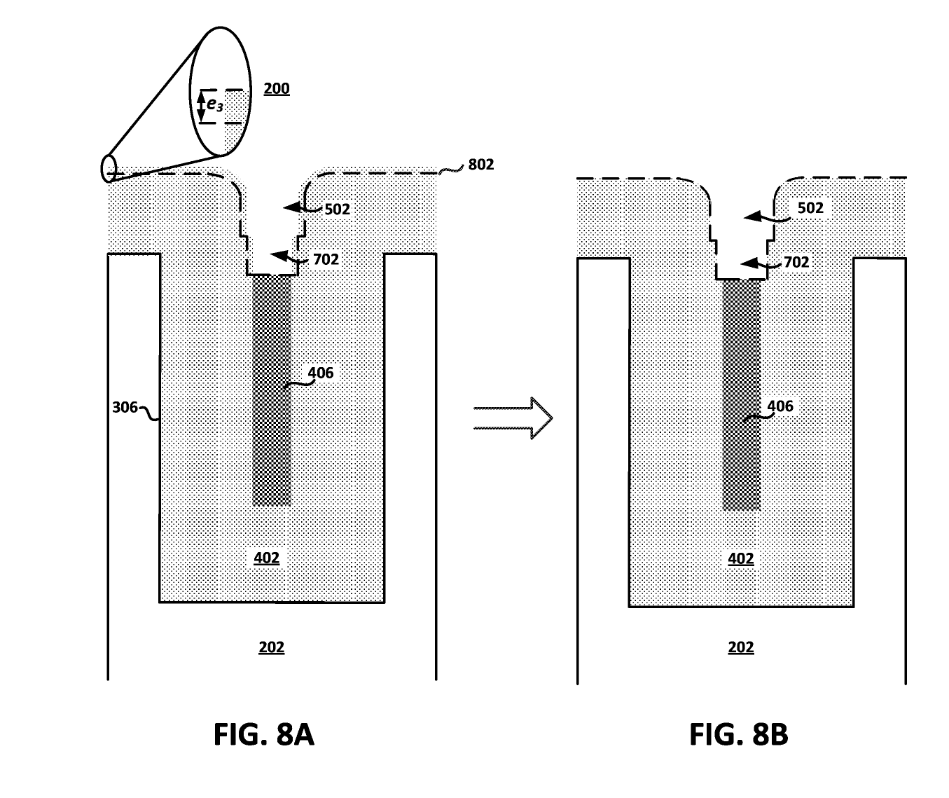

FIGS. 8A and 8B depict substrate 200 before and after a thickness e₃ of insulating layer 402 is isotropically etched, which allows for approximately the same amount of material to be etched regardless of the slope of the surface where the etching is taking place. In other words, the amount of insulating layer 402 that is etched from horizontal surfaces is approximately the same as the amount of insulating layer 402 that is etched from vertical surfaces. The isotropic nature of the etch is illustrated by line 802 that approximates the amount of insulating layer 402 that is removed from FIG. 8A to FIG. 8B during the etch. As can be seen from line 802, the amount of insulating material removed is approximately constant across the surface of insulating layer 402. If the etch for insulating layer 402 is selected properly, very little of mask layer 406 should be etched (e.g., the same etch discussed with respect to FIGS. 6A and 6B). Note that because the sidewalls of insulating layer 402 adjacent regions 502 and 702 were exposed, the width of region 502 grew by approximately 2*e₃ more (or 2*e₃+2*e₁ total from the initial width of region 502), and the width of region 702 grew by approximately 2*e₃ (or 2*e₃ total from the initial width of region 702). Put another way, there is a thickness e₃ less insulation layer 402 between the interior sidewall of insulation layer 402 and the sidewall 306.

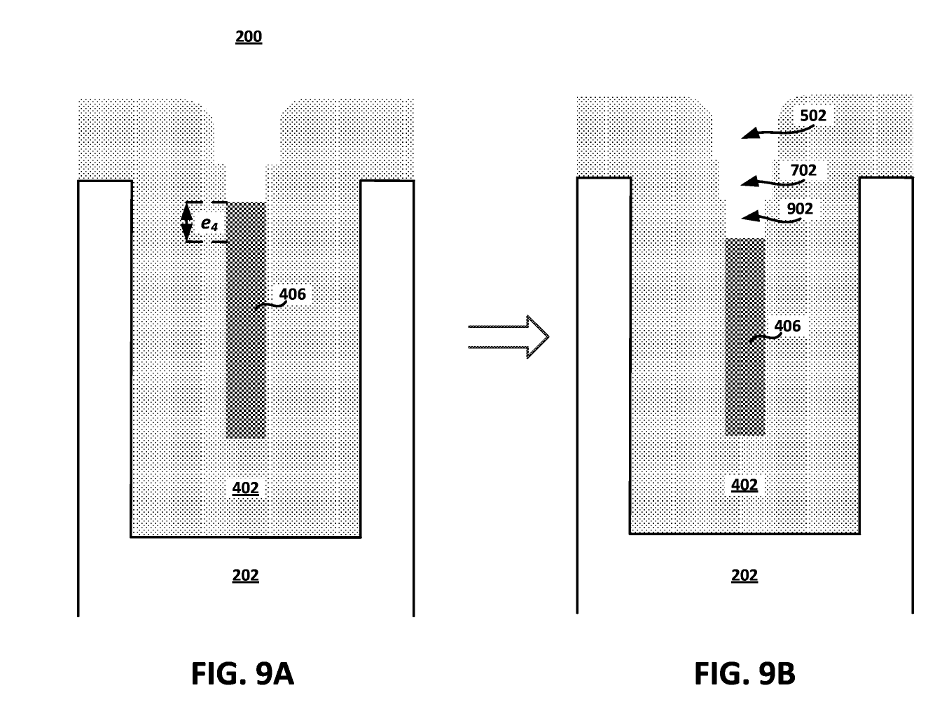

FIGS. 9A and 9B depict substrate 200 before and after etching a thickness e₄ of fill mask layer 406. By etching fill mask layer 406, region 902 defined by the newly exposed sidewalls of insulating material 402 is formed below regions 502 and 702. Region 902 is narrower than region 702 and has roughly the same width as regions 502 and 702 had when first formed (see FIG. 5 and FIG. 7, respectively) because the initial width of regions 902, 702, and 502 are all determined by the width of gap 404 (FIG. 4A).

Iterations of etching insulating layer 402 and mask layer 406 may continue until the desired taper of insulating layer 402 has been achieved. For example, the process of alternating the two etches (insulating layer and fill mask layer) may continue for some fixed number of iterations known to produce the desired taper. As another example, the process of alternating the two etches may continue until mask layer 406 is gone or has a thickness below some threshold. Each iteration of alternating etches widens the existing regions (e.g., regions 502, 702, and 902) by some amount and forms a new region of a width approximately the width of gap 404 (FIG. 4A). Accordingly, by adding iterations, the taper at the top of trench 302 (FIG. 3A) widens and a new “step” is added deeper in trench 302.

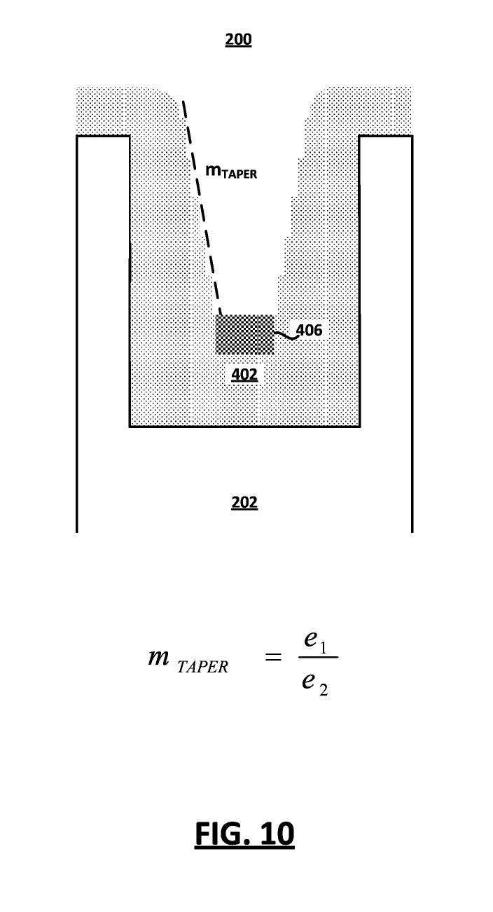

FIG. 10 depicts substrate 200 after six total iterations of etching mask layer 406 and insulating layer 402. If all etches of insulating layer 402 remove approximately the same amount of insulating layer 402 (i.e., e₁=e₃=e₂ₓ₋₁, where x is the number of etch iterations) and all etches of mask layer 406 remove approximately the same amount of mask layer 406 (i.e., e₂=e₄=e₂ₓ), where x is the number of etch iterations) then the slope, m_{TAPER}, of the taper of insulation layer 402 may be about e₁/e₂.

In other variations of the example process, the profile of insulating layer 402 may be different. For example, by etching different amounts of insulating layer 402 and mask layer 406 in different iterations, the profile of the insulating region may be controlled. In one instance, the profile of insulating layer 402 will have multiple different slopes along the exposed sidewall of insulating layer 402.

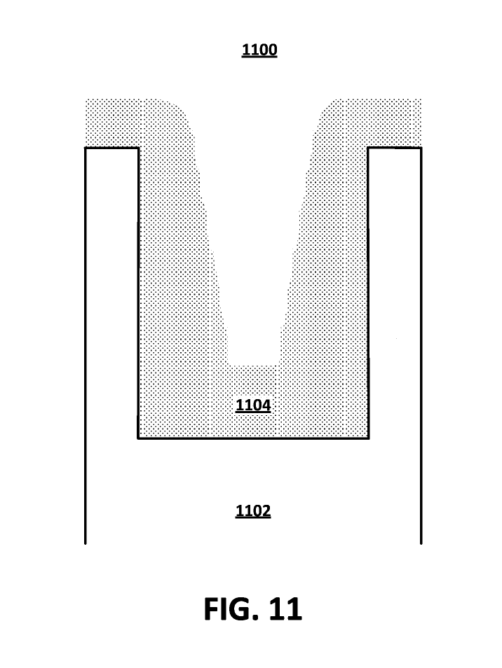

The insulating material has been depicted to have well-defined steps, with one step representing each deposition/etch cycle. However, in practice, it should be understood that the well-defined steps may not be present. For example, the profile of the insulating region may have a more linear shape. FIG. 11 depicts substrate 1100 that has another example of a profile for a tapered field plate dielectric that is not as ideal as the profile shown in FIG. 11.

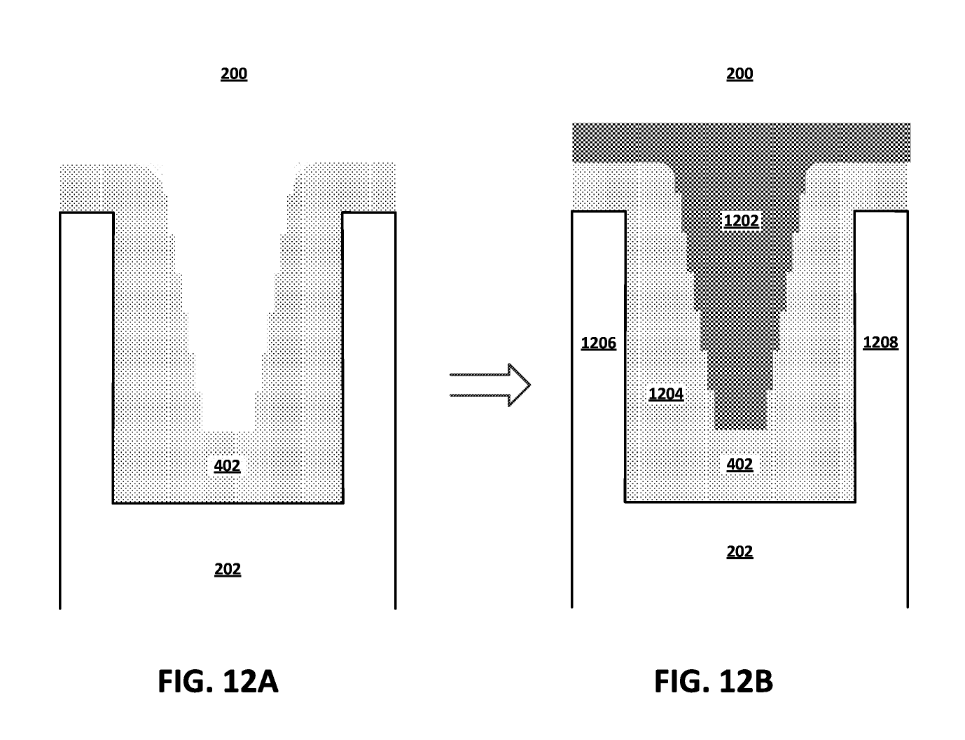

FIG. 12A depicts substrate 200 after all iterations of the alternating etch steps have been completed and any remaining portion of fill mask layer 406 has been removed. It should be understood that in variations of the example process, all of fill mask layer 406 may be etched during the iterations of the alternative etch steps. Other variations of the example process may also leave any remaining portions of fill mask layer 406 to be part of the field plate that is formed after deposition of a conductive material in trench formed by the taper in insulating layer 402 (see FIG. 12B).

FIG. 12B depicts substrate 200 after deposition of conductive material 1202 which fills the rest of trench 302 (not labeled) that was not filled by insulating layer 402 or was etched during the formation of the taper. Conductive material 1202 may be any number of materials, such as amorphous silicon, polycrystalline silicon, metal, and the like. If using a semiconductor for conductive material 1202, then conductive material 1202 may be in-situ doped as it is being deposited. The top of conductive material 1202 may be then be planarized using a chemical mechanical polishing (CMP) or etch-back step. Electrical contact may then be made to the remaining portion of conductive material 1202, which forms the tapered field plate. Once the field plate is formed, insulating layer 402 becomes tapered field plate dielectric region 1204.

Once tapered field plate dielectric 1204 is formed, and the surface of wafer 202 has been planarized (if required), semiconductor device fabrication flows may be performed to form active devices in active regions of substrate 200 (e.g., pillars of silicon 1206 and 1208). For example, a VTS HVFET process may be used to form HVFETs in silicon pillars 1206 and 1208.

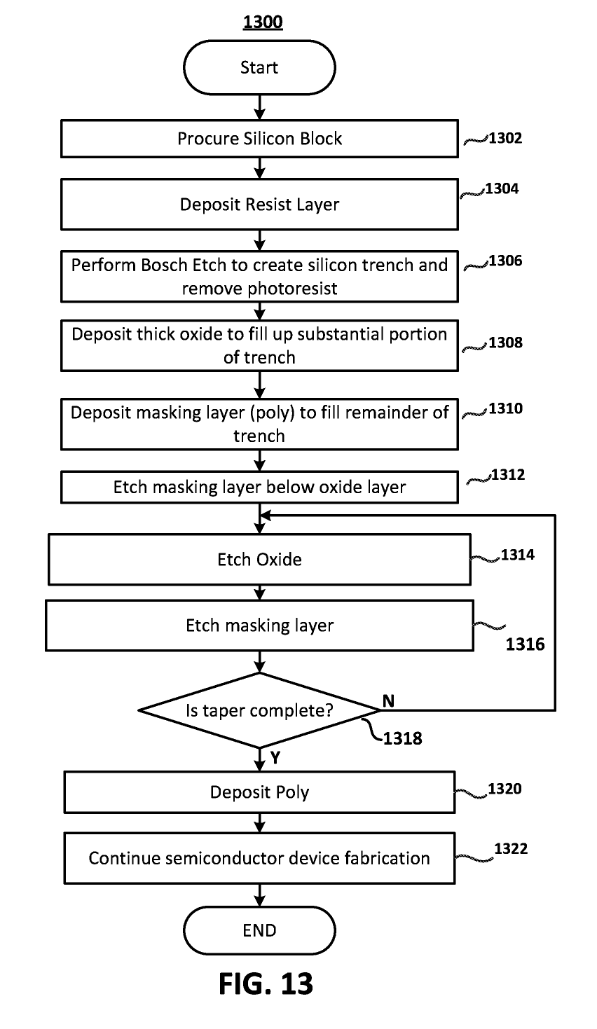

FIG. 13 depicts a flow chart for example process 1300 (similar to the example process described above with respect to FIGS. 2-12, for forming a tapered field plate dielectric region in a semiconductor process. In step 1302, a silicon wafer is obtained. The silicon wafer may have different layers of doping created with, for example, epitaxially grown layers of silicon (e.g., see FIG. 2A). In step 1304, a photoresist mask is patterned (e.g., see FIG. 2B). The photoresist mask defines the location and size of the trench that contains the tapered field plate and tapered field plate dielectric region. In step 1306, a DRIE (or Bosch etch) step is performed to define the trench for the tapered field plate (e.g., see FIG. 3A) and any remaining photoresist is striped (e.g. see FIG. 3B). In step 1308, a layer of oxide is deposited over vertical and horizontal surfaces of the substrate (e.g., see FIG. 4A). The deposited oxide fills a substantial portion of the trench but leaves a gap in the middle of the trench open. In step 1310, a poly silicon masking layer is deposited over the wafer and in the gap formed by the oxide deposition of step 1308 (e.g., see FIG. 4B). In step 1312, an etch of the polysilicon mask is performed to expose a portion of the sidewalls of the oxide layer in the gap (e.g., see FIG. 5). In step 1314, an isotropic oxide etch is performed to remove a certain thickness of the oxide deposited in step 1308 (e.g., see FIGS. 6A and 8A). Because the etch is isotropic (i.e., substantially isotropic), all exposed surfaces of the oxide layer should be etched by approximately the same amount. In step 1316, the polysilicon mask is etched by a further amount to expose a new portion of the sidewall of the oxide layer from step 1308 in the gap (e.g., see FIGS. 7B and 9B). In step 1318, it is determined whether the taper of the oxide layer has been completed (e.g., see FIG. 10). For example, this may be determined based on the number of oxide etch/poly etch iterations that have been performed. As another example, iterations of steps 1314 and 1316 may be repeated until a threshold thickness of poly (or no poly) remains. In step 1320, once the tapered field plate dielectric has been formed in the trench, polysilicon is deposited in the trench to form the tapered field plate (e.g., see FIG. 12B). A planarization step may be needed to ensure that the field plate and the surface of the wafer are coplanar. In step 1322 a MOSFET process flow is performed to form a HVFET in the silicon pillar adjacent the trench that contains the sloped field plate.

While example process 1300 has been described with respect to specific materials and layers, it should be understood that some layers may be optional and the materials of the wafer and layers may vary.

The above description of illustrated examples of the present invention, including what is described in the Abstract, are not intended to be exhaustive or to be limitation to the precise forms disclosed. While specific embodiments of, and examples for, the invention are described herein for illustrative purposes, various equivalent modifications are possible without departing from the broader spirit and scope of the present invention. Indeed, it is appreciated that the specific example voltages, currents, frequencies, power range values, times, etc., are provided for explanation purposes and that other values may also be employed in other embodiments and examples in accordance with the teachings of the present invention.

These modifications can be made to examples of the invention in light of the above detailed description. The terms used in the following claims should not be construed to limit the invention to the specific embodiments disclosed in the specification and the claims. Rather, the scope is to be determined entirely by the following claims, which are to be construed in accordance with established doctrines of claim interpretation. The present specification and figures are accordingly to be regarded as illustrative rather than restrictive.

What is claimed is:

1. A method of forming a tapered field plate dielectric region in a semiconductor wafer, the method comprising:
etching a trench in the semiconductor wafer;
depositing an insulating layer on the semiconductor wafer, including on sidewalls of the trench, wherein the insulating layer forms a gap in the trench open to the top of the trench;
depositing a masking layer on the insulating layer, wherein the masking layer fills at least a portion of the gap;
etching a first amount of the masking layer to expose a first sidewall portion of the insulating layer in the gap;
etching a second amount of the insulating layer, including the first sidewall portion of the insulating layer;
etching a third amount of the masking layer to expose a second sidewall portion of the insulating layer in the gap, wherein the second sidewall portion is deeper in the trench than the first sidewall portion; and
etching a fourth amount of the insulating layer, including the first sidewall portion and the second sidewall portion of the insulating layer.

2. The method of claim 1, wherein etching the first amount and etching the third amount are done in a solution including a hydrofluoric acid.

3. The method of claim 1 further comprising:
depositing a conductive material in the trench on the insulating layer; and
removing a portion of the conductive material outside of the trench.

4. The method of claim 3, wherein removing the portion of the conductive material outside of the trench includes performing a chemical mechanical polishing step.

5. The method of claim 1 further comprising:
etching a fifth amount of the masking layer to expose a third sidewall portion of the insulating layer in the gap, wherein the third sidewall portion is deeper in the trench than the first sidewall portion and the second sidewall portion; and
etching a sixth amount of the insulating layer, including the first sidewall portion, the second sidewall portion, and the third sidewall portion of the insulating layer.

6. The method of claim 1, wherein the masking layer comprises silicon.

7. The method of claim 1, wherein the insulating layer comprises oxide.

8. The method of claim 1 further comprising:
forming an active semiconductor device in the semiconductor wafer adjacent the trench.

9. The method of claim 1, wherein the first amount and the second amount are approximately equal.

10. The method of claim 1, wherein the second amount and the fourth amount are approximately equal.

11. The method of claim 9, wherein the first amount and the second amount are approximately equal.

12. A method of forming a tapered field plate dielectric region in a semiconductor wafer, the method comprising:
etching the semiconductor wafer to form a trench therein;
depositing an insulating layer on the semiconductor wafer, wherein after depositing, a gap is formed in the insulating layer within the trench;
depositing a masking layer on the insulating layer, wherein the masking layer fills at least a portion of the gap; and
alternatingly etching portions of the masking layer and the insulating layer within the gap to form a tapered insulating layer within the trench.

13. The method of claim 12, wherein etching of the masking layer is performed using a solution comprising a hydrofluoric acid.

14. The method of claim 12 further comprising:
depositing a conductive material in the trench on the insulating layer; and
removing a portion of the conductive material outside of the trench.

15. The method of claim 14, wherein removing the portion of the conductive material outside of the trench includes performing a chemical mechanical polishing step.

16. The method of claim 12, wherein the masking layer comprises silicon.

17. The method of claim 12, wherein the insulating layer comprises oxide.

18. The method of claim 12 further comprising:
forming an active semiconductor device in the semiconductor wafer adjacent the trench.

19. The method of claim 12, wherein alternatingly etching portions of the masking layer and the insulating layer comprises:
etching a first amount of the masking layer to expose a first sidewall portion of the insulating layer in the gap;
etching a second amount of the insulating layer, wherein the second amount comprises a first portion of the first sidewall portion of the insulating layer;
etching a third amount of the masking layer to expose a second sidewall portion of the insulating layer in the gap, wherein the second sidewall portion is deeper in the trench than the first sidewall portion; and
etching a fourth amount of the insulating layer, wherein the fourth amount comprises a second portion of the first sidewall portion and a first portion of the second sidewall portion of the insulating layer.

20. The method of claim 19, wherein the second amount and the fourth amount are approximately equal, and wherein the first amount and the second amount are approximately equal.
